(19) United States
(12) Patent Application Publication
(10) Pub. No.: US 2019/0110132 A1
(43) Pub. Date: Apr. 11, 2019

(54) Plate Spring

(71) Applicant: Vesper Technologies Inc., Boston, MA (US)

(72) Inventor: Robert J Littrell, Boston, MA (US)

(21) Appl. No.: 15/760,868

(22) PCT Filed: Sep. 19, 2016
(86) PCT No.: PCT/US2016/052461

§ 371 Date: Mar. 16, 2018

Related U.S. Application Data
(60) Provisional application No. 62/220,768, filed on Sep. 18, 2015.

(51) Int. Cl. H04R 17/02; H01L 41/27

(52) U.S. Cl. CPC H04R 17/025; B81B 3/0048; H01L 41/27

(57) ABSTRACT

A transducer and method for processing a MEMS transducer. In one aspect, the MEMS transducer includes a first plate and a second plate. The MEMS transducer can also include a spring substantially between the first plate and the second plate, the spring including first and second spring arms dimensioned to decrease vertical deflection mismatch between the first and second plates, relative to vertical deflection mismatch of the first and second plates independent of the spring.

### CLAIM OF PRIORITY

This application claims priority under 35 U.S.C. § 119(e) to U.S. Provisional Application No. 60/220,768, filed Sep. 18, 2015, the entire contents of which are incorporated herein by reference.

### BACKGROUND

Micro-electrical-mechanical systems (MEMS) technology has enabled the development of acoustic transducers such as microphones using silicon-wafer deposition techniques. Microphones fabricated this way are commonly referred to as MEMS microphones and can be made in various forms such as capacitive microphones or piezoelectric microphones. MEMS capacitive microphones and electret condenser microphones (ECMs) are used in consumer electronics and have an advantage over typical piezoelectric MEMS microphones in that they have historically had greater sensitivity and lower noise floors. However, each of these more ubiquitous technologies has its own disadvantages. For standard ECMs, they cannot be mounted to a printed circuit board using the typical lead-free solder processing commonly used to attach microchips to the board. MEMS capacitive microphones, which are often used in cell phones, have a backplate that is a source of noise in the microphones. MEMS capacitive microphones also have a smaller dynamic range than typical piezoelectric MEMS microphones.

### SUMMARY

In some implementations, a MEMS transducer can include a spring to reduce vertical deflection mismatch between adjacent plates. The spring can be added between the adjacent plates to make the vertical deflection between the adjacent plates more similar. As such, the gap size between the adjacent plates can be reduced due to the reduction in vertical deflection mismatch between the plates. The MEMS transducer can be fabricated by performing processing on a substrate. The processing can include alternating layers of electrode and piezoelectric being deposited on the substrate. The spring and the adjacent plates can be defined by etching of the deposited layers.

One aspect of the subject matter described in this specification is embodied in a MEMS transducer including a first plate and a second plate. The MEMS transducer also including a spring substantially between the first plate and the second plate, the spring comprising first and second spring arms dimensioned to decrease vertical deflection mismatch between the first and second plates, relative to vertical deflection mismatch of the first and second plates independent of the spring.

Other implementations of this and other aspects include corresponding systems, apparatus, and computer programs, configured to perform the actions of the methods, encoded on computer storage devices.

Implementations may each optionally include one or more of the following features. For instance, the transducer can include a plate including a piezoelectric layer and a pair of electrode layers sandwiching the piezoelectric layer. In certain aspects, the transducer further includes a substrate, wherein the first plate comprises a first plate base, a first plate body and a first plate end, wherein the second plate comprises a second plate base, a second plate body and a second plate end, and wherein the first and second plates are connected in a cantilevered arrangement over the substrate by having the first and second plate bases attached to the substrate, the first and second plate ends substantially converging towards a common point, and with each plate body free from the substrate and with each plate end free and unattached. The transducer can also include a size of a gap between the first and second plates that is reduced, relative to a size of a gap between the first and second plates independent of the spring. The transducer can further include the spring being dimensioned such that a length and a width of the spring provide an acceptable amount of in-plane stiffness of the plate.

In certain aspects, the transducer further includes a gap between the first plate and the second plate, wherein the spring is located along the gap at a position that decreases vertical deflection mismatch between the first and second plates. The gap between the first plate and the second plate can be proportional to gaps between the first and second spring arms and the first and second plates. In some aspects, the transducer includes an acoustic transducer. The acoustic transducer can be a microphone. The plate of the transducer can include a tapered transducer beam. In certain aspects, the spring includes a plurality of stress relieving endpoints. The plurality of stress relieving endpoints can prevent the spring from breaking. The dimensions of the plurality of stress relieving endpoints can be based on a calculated stress value at a turn of the spring. In some aspects, the spring is dimensioned such that a length and a width of the spring provide an acceptable amount of out-of-plane stiffness of a plate. Further, the spring can be dimensioned such that a length and a width of the spring is based on a maximum principal stress of the spring.

In other implementations, a method includes depositing a first electrode layer on a substrate; depositing a first piezoelectric layer on the first electrode layer; depositing a second electrode layer on the first piezoelectric layer; etching the deposited layers to define a first plate and a second plate that are connected in a cantilevered arrangement over the substrate, each of the plates including a plate base attached to the substrate, a plate body free from the substrate, and a plate end free from the substrate, the first and second plate ends substantially converging towards a common point; and etching the deposited layers to define a spring that is adjacent to the first and second plates, the spring including a first spring arm and a second spring arm that are each dimensioned to decrease vertical deflection mismatch between the first and second plates, relative to vertical deflection mismatch of the first and second plates independent of the spring.

In other implementations, a size of a gap between the first and second plates is reduced, relative to a size of a gap between the first and second plates independent of the spring. The spring is dimensioned such that a length and a width of the spring provide an acceptable amount of in-plane stiffness of a plate. In still other implementations, the spring comprises a plurality of stress relieving endpoints. In yet other implementations, the spring is located along a gap between the first plate and the second plate, the spring being located at a position that decreases the vertical deflection mismatch between the first and second plates.

The details of one or more embodiments are set forth in the accompanying drawings and the description below. Other features and advantages will become apparent from the description, the drawings, and the claims.

### BRIEF DESCRIPTION OF THE DRAWINGS

FIG. 1 is a diagram of a plate with gap controlling geometry, according to certain exemplary aspects.

FIG. 2 is a diagram of four triangular plates with gap controlling geometry, according to certain exemplary aspects.

FIG. 3 is a diagram illustrating modeled deflection of plates, according to certain exemplary aspects.

FIG. 4 is a chart illustrating modeled deflection along the gap of two adjacent plates with gap controlling geometry, according to certain exemplary aspects.

FIGS. 5A, 5D are each an illustration of an exemplary gap reducing spring, according to certain aspects.

FIG. 5B is an illustration of adjacent plates, according to certain exemplary aspects.

FIG. 5C is an illustration of an exemplary gap reducing spring, according to certain aspects.

FIGS. 6A, 6C are each an illustration of an exemplary gap reducing spring, according to certain aspects.

FIG. 6B is an illustration of adjacent plates, according to certain exemplary aspects.

FIGS. 7A, 7C are each an illustration of an exemplary gap reducing spring, according to certain aspects.

FIG. 7B is an illustration of adjacent plates, according to certain exemplary aspects.

FIG. 8 is an exemplary chart illustrating performance of gap reducing spring designs and geometries, according to certain aspects.

FIG. 9A illustrates a top view of modeled deflection without gap reducing springs, according to certain exemplary aspects.

FIG. 9B illustrates an angled view of modeled deflection without gap reducing springs, according to certain exemplary aspects.

FIG. 10A illustrates a top view of modeled deflection with gap reducing springs, according to certain exemplary aspects.

FIG. 10B illustrates an angled view of modeled deflection with gap reducing springs, according to certain exemplary aspects.

FIG. 11 is a flow chart illustrating an exemplary process for manufacturing a transducer, according to certain aspects.

Like reference numbers and designations in the various drawings indicate like elements.

### DETAILED DESCRIPTION

When fabricating a microphone with gap controlling geometry (such as that described in U.S. Pat. No. 9,055,372, the entire contents of which are incorporated herein by reference), sensor yield is reduced due to manufacturing non-idealities. For example, if the in-plane residual stress (e.g., of a beam or a plate) is not the same in two orthogonal in-plane directions, and this difference varies through the thickness of the film stack, then the tips of the plates can have different amounts of vertical deflection. Generally, vertical deflection of a plate includes a degree to which the plate is displaced due to stress on the plate. The vertical deflection of a plate can be caused by in-plane stress, out-of-plane stress, or both.

In an example, a plate includes (or is the same as) a cantilevered beam as described in U.S. Pat. No. 9,055,372. In this example, a plate includes a MEMS fabricated plate, such as, e.g., a plate with an electrode layer, a piezoelectric layer, and other electrode layer. In this example, the electrode layers sandwich the piezoelectric layer. The plates could also have different amounts of vertical deflection if they were slightly different lengths. This different deflection of adjacent plates is undesirable because it increases the gap between plates and reduces the acoustic resistance through the sensor as described in U.S. Pat. No. 9,055,372. For example, a MEMS microphone transducer design can have two 0.5 um thick layers of aluminum nitride (AIN) stacked on top of each other. The residual film stress in the X-direction (σₓₓ_{_}ᵣₑₛ) for a bottom layer can be 400 MPa and the residual film stress in the Y direction (σ_{yy}_{_}ᵣₑₛ) can be 435 MPa. The residual film stress in both the X-direction and Y-direction can be 400 MPa for a top layer. In this example, the bottom layer refers to the bottom layer of a plate (e.g., a plate comprising a plurality of electrode layers). The top layer refers to the top layer of the plate.

This difference in X versus Y stress can cause a plate deflection of approximately 15 um for 380 um long plates.

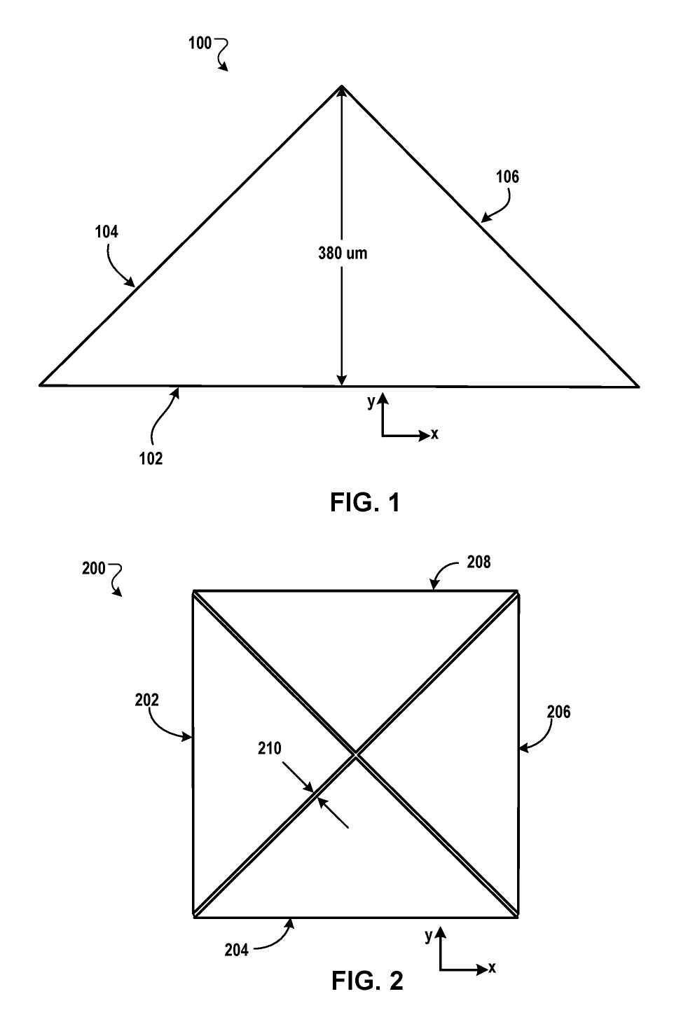

FIG. 1 is a diagram of a plate 100 with gap controlling geometry, according to certain exemplary aspects. In certain aspects, the plate 100 can be one of four plates in a gap controlling geometry. Generally, gap controlling geometry includes geometry that controls the gaps between adjacent plates. The gaps between adjacent plates can be controlled to adjust the stress between the adjacent plates. The base 102 of the plate 100 can be fixed to a substrate. As such, the remaining structure of the plate can be free to move, thereby creating a fixed-free-free plate. In this instance, the base 102 of the plate can be attached to a substrate, a first side 104 of the plate 100 can be free from the substrate, and a second side 106 of the plate 100 can also be free from the substrate. Referring to the example of FIG. 1, the length of the plate 100 can be 380 um from base 102 to tip and the thickness can be 1 um thick aluminum nitride (AIN). The exemplary plate 100 can further include two 500 nm thick layers which add up to a total of 1 um. In certain aspects, the plate 100 can be a fixed triangular plate.

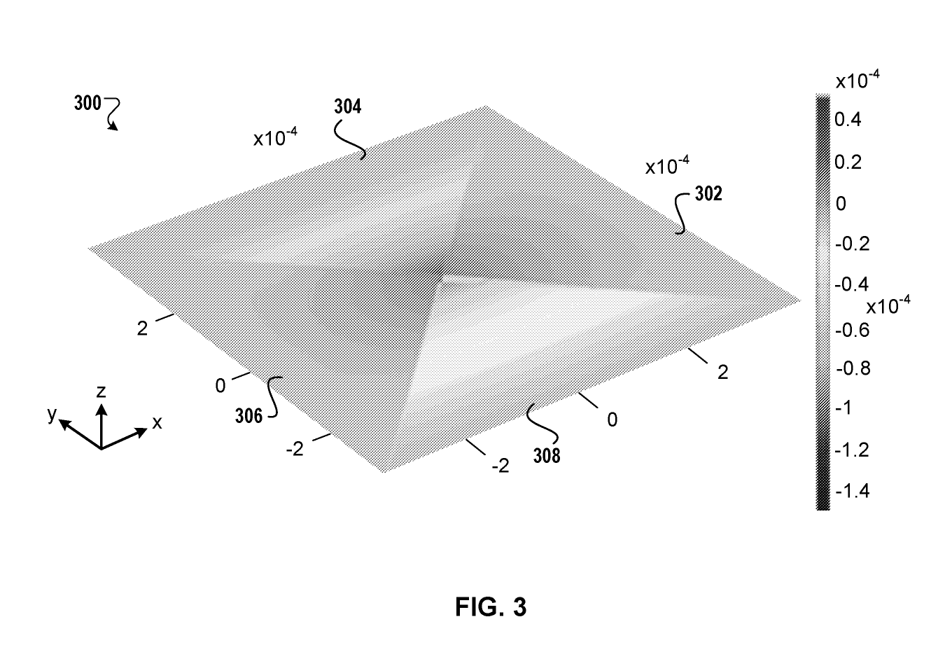

FIG. 2 is a diagram of four triangular plates 200 with gap controlling geometry, according to certain exemplary aspects. The four triangular plates 200 include a first triangular plate 202, a second triangular plate 204, a third triangular plate 206 and a fourth triangular plate 208. The four triangular plates 200 can be cantilever plates that bend up or down due to variations in residual stress among the four triangular plates 200. However, the gap controlling geometry of the four triangular plates 200 can control the gaps between adjacent plates to remain relatively small. As such, the gap controlling geometry can yield smaller gaps between adjacent plates in comparison to gaps between two facing rectangular cantilevers. For example, the gap controlling geometry can yield a small gap 210 between the first triangular plate 202 and the adjacent second triangular plate 204. In some aspects, mismatches in stress in the X and Y directions can cause the plates 200 to deflect differently and have gaps that are much larger than those created when the stress in X and Y directions is the same. As such, it would be beneficial to mitigate the differences in deflection between the four triangular plates 200. In this instance, the stress among the four triangular plates 200 can be adjusted in order to mitigate the differences in deflection between the four triangular plates 200.

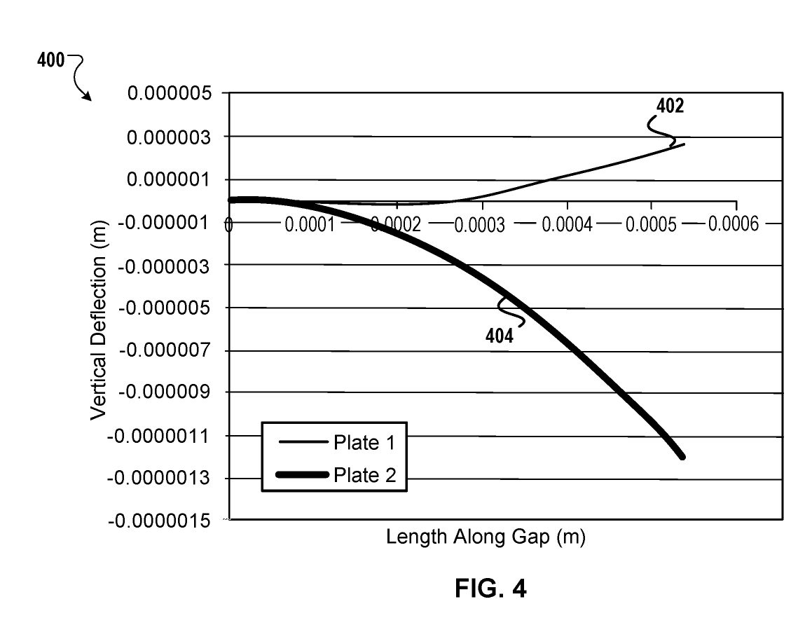

FIG. 3 is a diagram illustrating modeled deflection of plates 300, according to certain exemplary aspects. In FIG. 3, the modeled deflection of four plates is illustrated. The modeled deflection of plates 300 includes a first modeled plate 302, a second modeled plate 304, a third modeled plate 306, and a fourth modeled plate 308. The modeled deflection of plates 300 can include a bottom layer and a top layer. Each of the bottom layer and the top layer can include a respective amount of stress. In this example, the bottom layer stress is 400 MPa in the X-direction and 435 MPa in the Y-direction, and the top layer stress is 400 MPa in both the X and Y directions. As such, the two opposing pairs of plates have matched deflection. Therefore, the first modeled plate 302 would have a matched deflection with the third modeled plate 306, and the second modeled plate 304 would have a matched deflection with the fourth modeled plate 308. However, the difference in X and Y stress causes the adjacent plates to have different vertical deflections. The different vertical deflections among the adjacent plates can ultimately enlarge the gap between plates. For example, the difference in X and Y stress among the modeled deflection of plates 300 can cause the gap between the first modeled plate 302 and the second modeled plate 304 to become larger, and cause the gap between the first modeled plate 302 and the fourth modeled plate 308 to also become larger.

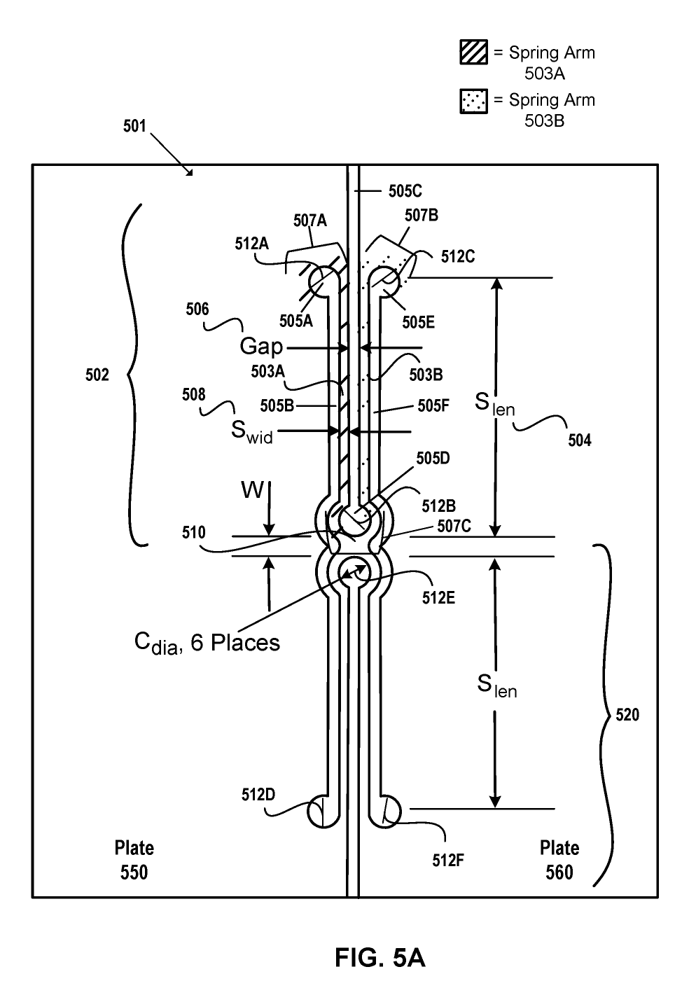

FIG. 4 is a chart 400 illustrating modeled deflection along the gap of two adjacent plates with gap controlling geometry, according to certain exemplary aspects. The chart 400 of FIG. 4 corresponds to the conditions used for FIG. 3 with respect to two adjacent plates, i.e., plate 1 and plate 2. In this example, curve 402 illustrates the vertical deflection of plate 1 along a length of a gap between plate 1 and plate 2, which in this example is adjacent to plate 1. In this example, curve 404 illustrates the vertical deflection of plate 2 over a length along the gap between the plate 1 and plate 2. In this example, the bottom layer stress between the plate 1 and plate 2 is 400 MPa in the X-direction and 435 MPa in the Y-direction, and the top layer stress between plate 1 and plate 2 is 400 MPa in both the X and Y directions. As indicated by the chart 400 that describes the length along the gap between the two adjacent plates vs. the vertical deflection of each of the two adjacent plates, the gap between the two plates is largest at the tip, which can be 15 um.

By adding gap-reducing springs between the plates (i.e., plate 1 and plate 2) in the gap controlling geometry, the vertical deflection of adjacent plates can be made more similar, reducing the gap size between plates. Several metrics can be used to determine the proper design of gap-reducing springs including maximum principal stress in the spring structure due to in-plane residual stress, impact on sensitivity, reduction in gap size, and the like. Maximum principal stress due to in-plane residual stress is determined by modeling the plates and springs with the X and Y stress values given above. This represents a particular scenario. For example, higher maximum principal stress is associated with a greater likelihood of spring breakage while a lower maximum principal stress is associated with a lower likelihood of spring breakage. Generally, maximum principal stress includes the limit of maximum stress that a system can undergo before breaking. As such, in this instance the maximum principle stress can correspond to the maximum amount of stress at elastic limit in simple tension of the springs between corresponding adjacent plates. Therefore, lower maximum principal stress in the spring structure can be desirable.

Impact on sensitivity is evaluated by comparing the sum of the stress in the X-direction (σₓₓ_{_}ₚ) and that in the Y-direction (σ_{yy}_{_}ₚ) in the active device area, such as an active area of a substrate or of one or more plates, due to applied uniform acoustic pressure of the gap-controlling geometry to that of the same geometry with gap-reducing springs. The active device area can be an area of the substrate or of the one or more plates that includes sensor electrodes. This may be different from a non-active area which does not have electrodes that contributes to the overall sensor capacitance and output voltage of the device. The active device area is determined by maximizing the output energy as described in U.S. Pat. No. 8,531,088, the entire contents of which are incorporated herein by reference. It can be desirable to have as little reduction in sensitivity as possible. The reduction in gap size is determined by applying the same particular scenario residual stress values given above and comparing the vertical deflection mismatch of the design with the gap-reducing spring to that without the gap-reducing spring. Generally, the vertical deflection mismatch between plates includes the difference in vertical deflection between two or more plates.

Described herein are example spring designs to accomplish the reduction in gap size with minimal reduction on sensitivity and low principal stress due to in-plane residual stress. In some aspects, in-plane residual stress can include stress that remains at the plates from manufacturing. Further, the in-plane residual stress can correspond to stress that occurs within the same plane as the plate.

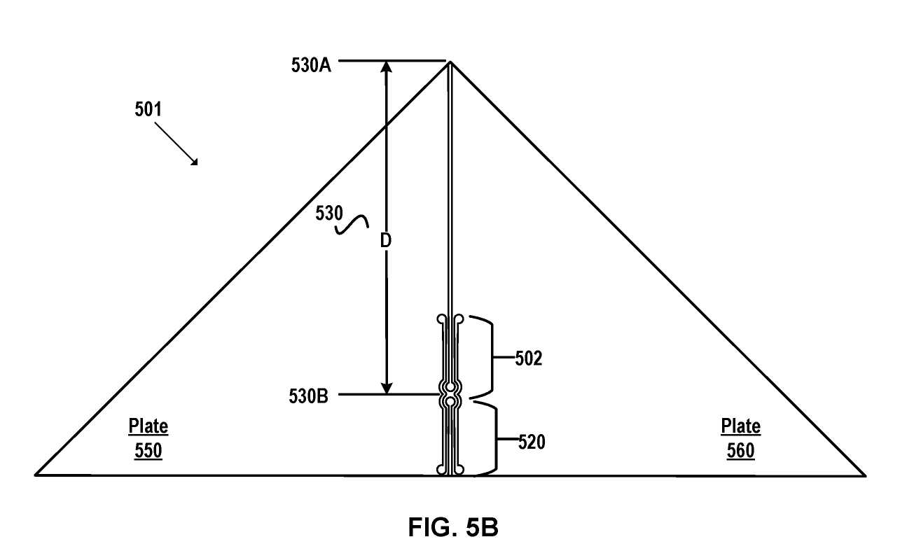

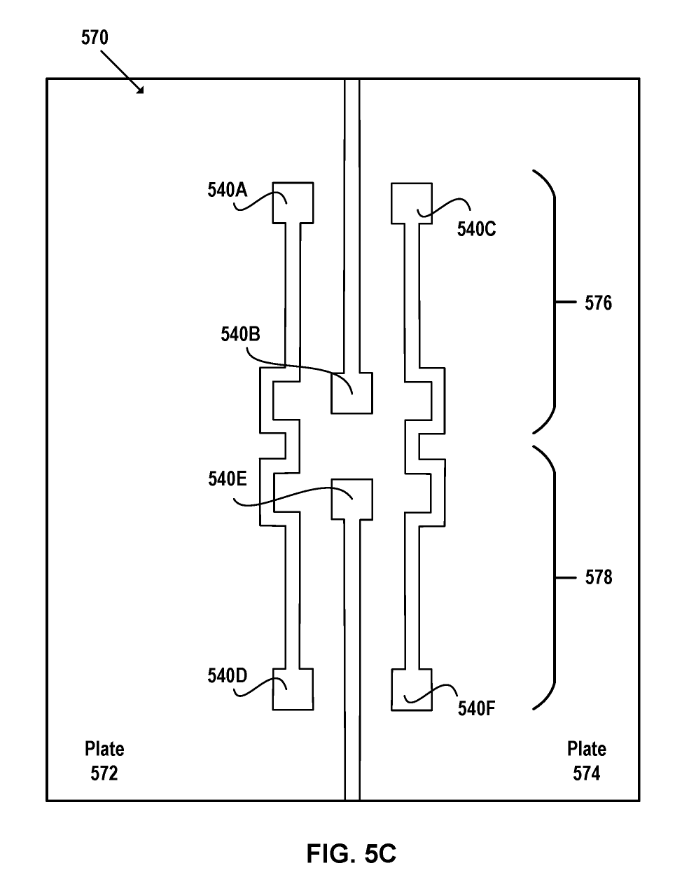

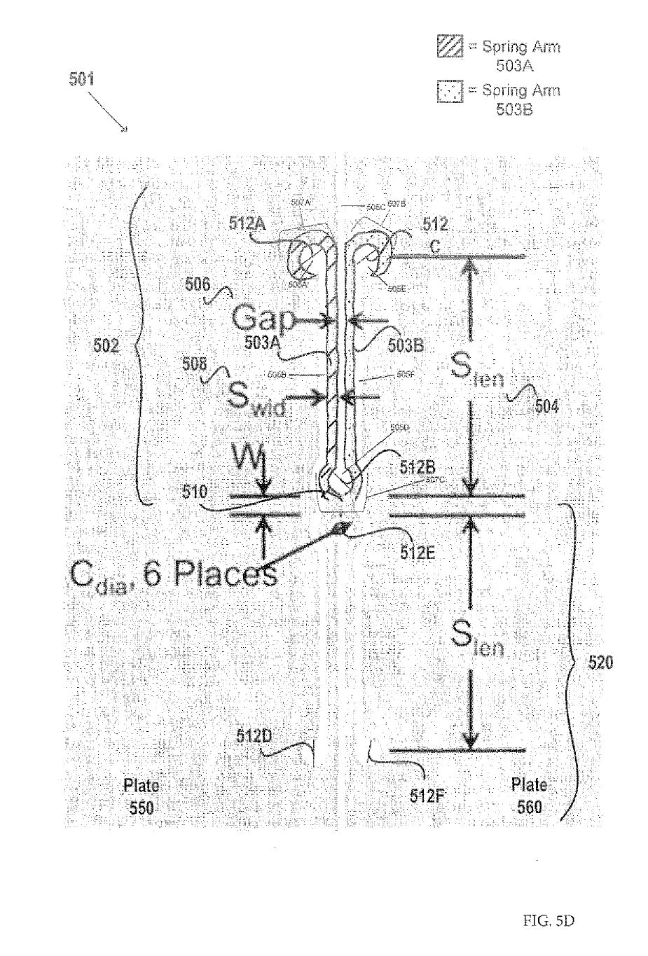

Referring to FIG. 5A, acoustic transducer 501 (or a portion of acoustic transducer) includes plates 550, 560 and springs 502, 520. In this example, acoustic transducer 501 includes an acoustic transducer with gap controlling geometry, e.g., as described in U.S. Pat. No. 9,055,372. In this example, each of springs 502, 520 is a gap reducing spring 502 connecting the two adjacent plates 550 and 560. In this example, spring 502 includes spring arms 503A, 503B. For example, spring arm 503A includes the hatched (shaded) portions surrounding the etched portions of plate 550. In this example, the etched portions are shown as the white areas and include etched portions 505A, 505B, 505C, 505D. Spring arm 503B includes the dotted portions surrounding the etched portions of plate 560.

In this example, the etched portions are shown as the white areas and include etched portions 505E, 505F, in addition to 505C, 505D. The size of the spring arms surrounding or in proximity to the etched areas may vary. One particular example is shown here. The spring 502 is associated with a spring arm length 504 (Sₗₑₙ), a gap 506 between the plates 550 and 560, respective widths of the spring arms 503A and 503B (S_{wid}), and stress relieving endpoints 507A, 507B. In this example, stress relieving endpoint 507A is included in spring arm 503A and stress relieving endpoint 507B is included in spring arm 503B. Spring 502 also include stress relieving endpoint 507C. The stress relieving endpoints of each spring can prevent the ends of the spring from breaking or otherwise snapping off, e.g., by relieving stress of the spring. In this example, width 508 of spring arm 503A is denoted as S_{wid}. In certain aspects, the spring 502 can be etched directly into the plates 550 and 560. Further, the plates 550 and 560 can be defined by etching of a substrate or material. (That is, the etching of the material forms the various plates as well as defining a spring that is adjacent to the plates). Each of the stress relieving endpoints includes a particular one of diameters 512A, 512B, 512C, 512D, 512E, 512F (C_{dia}). In some aspects, one of the diameters 512A-F of each of the stress relieving endpoints is the same. In FIG. 5A, there are six total stress relieving endpoints 507A, 507B, 507C, 507D, 507E, 507F that are circular in shape, however, as would be realized by one of ordinary skill in the art, the number and shape of the stress relieving endpoints can be adjusted. In certain aspects, the spring 502 of FIG. 5A can further be connected by a portion 510 with a width to a second spring 520 between the same two adjacent plates 550 and 560. In some aspects, the spring 520 and the plates 550 and 560 are both made of similar material. The material can include a film stack that is used to build the structure of the spring 520 between the two adjacent plates 550 and 560. The second spring 520 can share the above-described features of spring 502, including, e.g., arms and stress relieving endpoints.

Referring to FIG. 5B, acoustic transducer 501 includes adjacent plates 550, 560, according to certain exemplary aspects. The adjacent plates can include a distance (D) 530 from the tip 530A of the plates to the center 530B of the springs 502, 520. Each of springs 502, 520 can be placed so that it connects two adjacent plates 550 and 560.

Referring to FIG. 5C, acoustic transducer 570 includes plates 572, 574 (which are adjacent to each other) and gap reducing springs 576, 578. In this example, spring 576 includes stress relieving end points 540A, 540B and 540C. Spring 578 includes stress relieving end points 540E, 540D and 540F. In this example, the stress relieving endpoints 540A-F of springs 576, 578 between two adjacent plates 572, 574 may be square or rectangular, rather than being circular or elliptical.

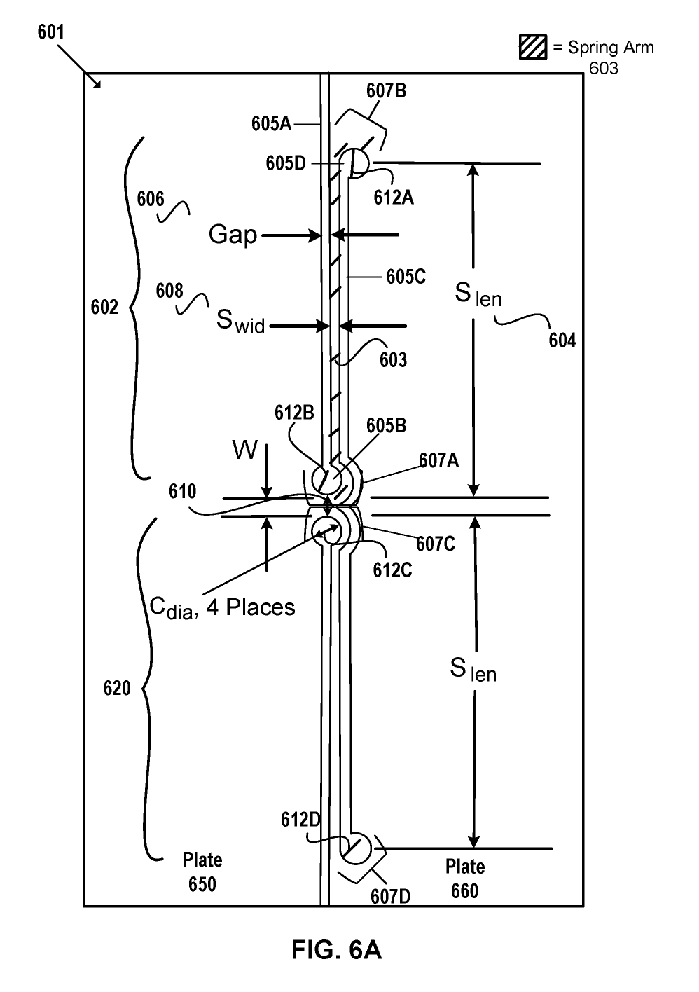

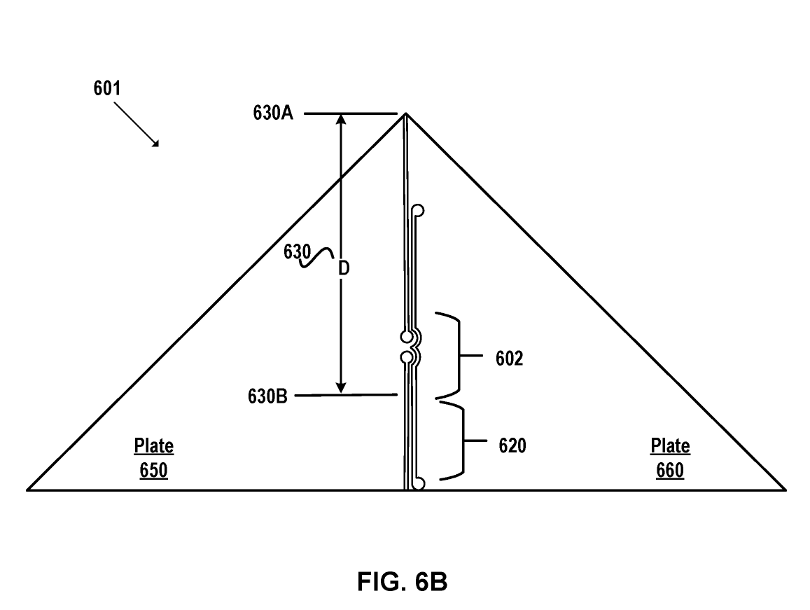

Referring to FIG. 6A, acoustic transducer 601 includes springs 602, 620 and plates 650, 660, which are adjacent to each other. In this example, spring 602 includes spring arm 603, with a spring arm length 604 (Sₗₑₙ). For example, spring arm 603 includes the hatched (shaded) portions surrounding etched portions of plate 560. In this example, the etched portions are shown as white areas and include etched portions 605A, 605B, 605C and 605D. In this example, there is a gap 606 between the plates 650 and 660, a width 608 of the spring arm (S_{wid}), and one or more stress relieving endpoints 607A, 607B, 607C, 607D. In this example, stress relieving endpoint 607B is included in spring arm 603. Spring 602 also includes stress relieving endpoint 607B. The stress relieving endpoints 607A, 607B, 607C, 607D of a spring can prevent the ends of the spring from breaking or otherwise snapping off, e.g., by relieving stress of the spring. In this example, width 608 of spring arm 603 is denoted as S_{wid}. In certain aspects, the spring 602 can be etched directly into the plates 650 and 660. Further, the plates 650 and 660 can be defined by etching of a substrate or material. (That is, the etching of the material forms the various plates as well as defining a spring that is adjacent to the plates). Each of the stress relieving endpoints 607a, 607b, includes a particular diameter 612A, 612B, 612C, and 612D (C_{dia}). In some aspects, the diameter 612A-D of each of the stress relieving endpoints 607A, 607B is the same.

Referring to FIG. 5D, a variation of FIG. 5A is shown in which an example of the boundary of each of spring arms 503A, 503B is shown.

In FIG. 6A, there are four total stress relieving endpoints 607A, 607B, 607C, 607D that are circular in shape. In certain aspects, the spring 602 of FIG. 6A can further be connected by a portion 610 to a second spring 620 between the same two adjacent plates 650 and 660. In this example, the second spring 620 includes two stress relieving endpoints 607C and 607D. The second spring 620 can ultimately share the features of spring 602, including, e.g., arms and stress relieving endpoints.

Referring to FIG. 6B, acoustic transducer 601 includes adjacent plates 650 and 660, according to certain exemplary aspects. The adjacent plates can include a distance (D) 630 from the tip 630a of the plates to the center 630b of the springs 602, 620. Each of springs 602, 620 can be placed so that it connects two adjacent plates 650 and 660.

Referring to FIG. 6C, a variation of FIG. 6A is shown in which an example of the boundary of spring arm 603 is shown.

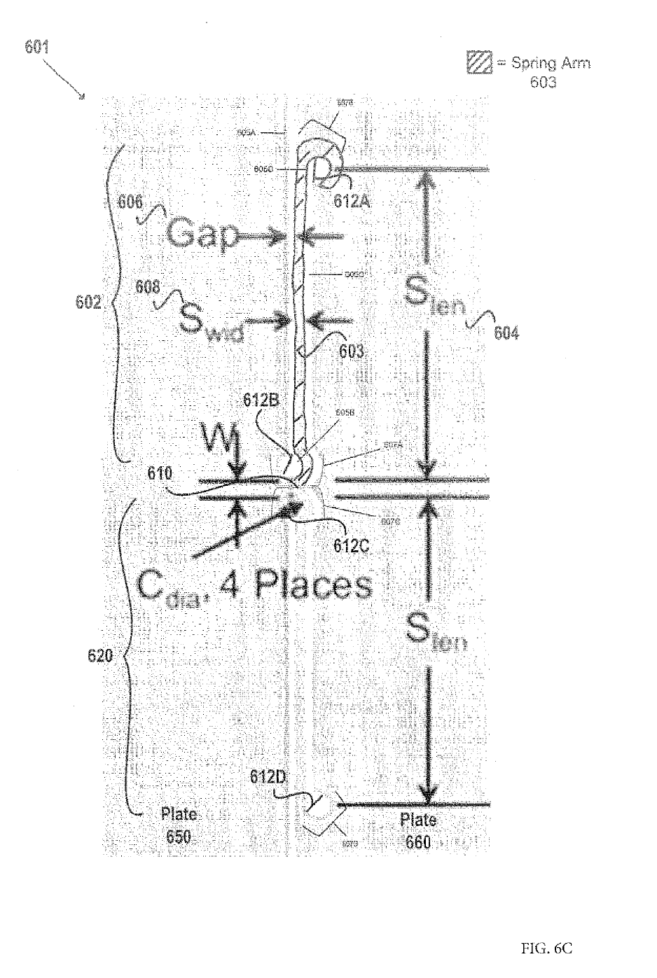

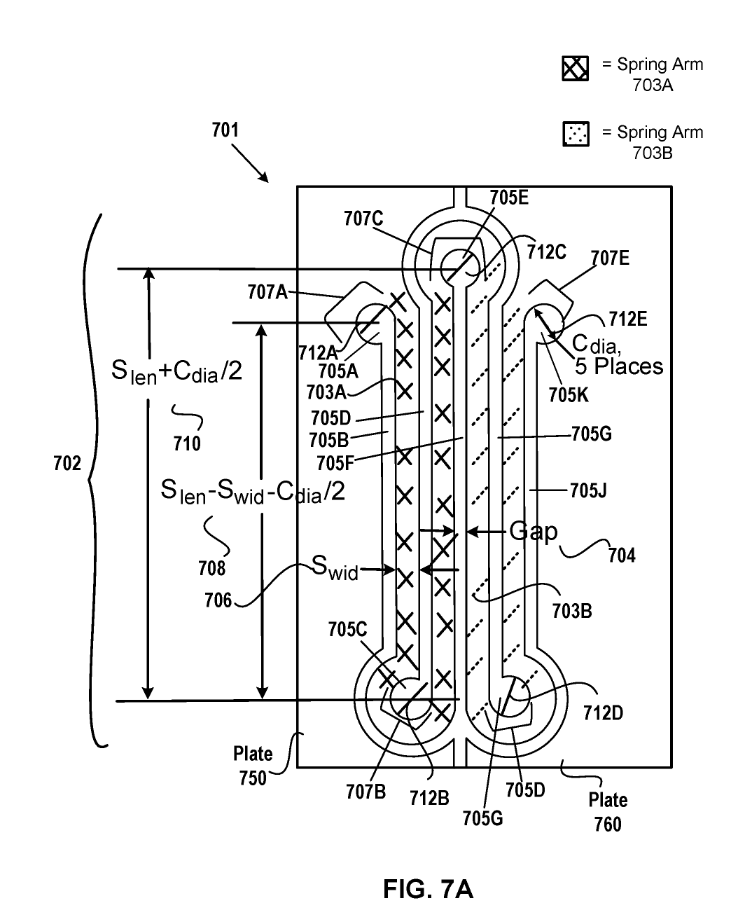

Referring to FIG. 7A, acoustic transducer 701 includes plates 750, 760 and spring 702. In this example, spring 702 is a gap reducing spring 702 connecting two adjacent plates 750 and 760. In this example, spring 702 includes spring arms, 703A, 703B. For example, spring arm 703A includes hatched cross portions surrounding the etched portion in plate 750. In this example, the etched portions are shown as the white areas and include etched portions 705A, 705B, 705C, 705D, 705E, 705F. Spring arm 703B includes dotted portions surrounding the etched portion in plate 760. In this example, the etched portions are shown as the white areas and include etched portions 705E, 705F, 705G, 705H, 705I, 705J. The spring 702 is associated with a first spring arm length 708 (Sₗₑₙ−S_{wid}−C_{dia}/2) and a second spring arm length 710 (Sₗₑₙ−C_{dia}/2). The spring 702 can also be associated with a gap 706 between the plates 750 and 760, respective widths of the spring arms 703A, 703B (S_{wid}), and stress relieving endpoints 707A, 707B, 707C, 707D, 707E. Each of the stress relieving endpoints includes a particular diameter 712A, 712B, 712C, 712D, 712E (C_{dia}). In this example, stress relieving endpoints 707A and 707B are included in spring arm 703A, and stress relieving endpoints 707D and 707E are included in spring arm 703B. Spring 702 also includes stress relieving endpoint 702C. The stress relieving endpoints of each spring can prevent the ends of the spring from breaking or otherwise snapping off, e.g., by relieving stress of the spring. In certain aspects, the spring 702 can be etched directly into the plates 750 and 760. Further, the plates 750 and 760 can be defined by etching of a substrate or material. (That is, the etching of the material forms the various plates as well as defining a spring that is adjacent to the plates.) In some aspects, the diameter 712A-E of each of the stress relieving endpoints 707A-E is the same. In FIG. 7A, there are five total stress relieving endpoints 707A-E that are circular in shape, however, as would be realized by one of ordinary skill in the art, the number and shape of the stress relieving endpoints can be adjusted.

Referring to FIG. 7B, acoustic transducer 701 includes adjacent plates 750, 760, according to exemplary aspects. The adjacent plates can include a distance (D) 730 from the tip 730a of the plates to the center of the spring 730b of the spring 702. The spring 702 can be placed so that it connects two adjacent plates 750 and 760.

In certain aspects, the particular spring geometry of a spring design is selected in order to meet design requirements. Generally, there is a trade-off between gap size reduction and impact on sensitivity. A very stiff spring will reduce the gap significantly but will also reduce the sensitivity significantly relative to a compliant spring, which will have relatively less impact on sensitivity and gap size as well. Stiffer springs will also typically have higher principal stress due to residual film stress. Ideally, the spring is compliant in the in-plane direction of a plate and stiff in the out-of-plane direction of the plate. In an example, a spring can be dimensioned such that a length and width of the spring provide an acceptable amount of in-plane stiffness of a plate. Generally, a spring that is compliant in the in-plane direction includes a spring that is tolerant of a certain amount of deflection in the in-plane direction. On the other hand, a spring that is stiff in the out-of-plane direction is generally a spring that is resistant towards a certain amount of deflection in the out-of-plan direction.

In order to select a particular spring geometry, a maximum principal stress can be first selected. In certain aspects, the maximum principal stress is less than the ultimate strength of a material with some factor of safety. For example, a maximum principal stress of 500 MPa can be selected and designs can be sized to have approximately this amount of stress for the particular residual stress condition described above. In this example, the spring width (S_{wid}) can be selected as 1 um, because this size can be built with accuracy and precision. An increase in spring width (S_{wid}) may be undesirable because it can cause a large increase in the in-plane stiffness relative to the out-of-plane stiffness. Further, the location of the spring along the gap (D) can be selected to minimize the vertical deflection mismatch between plates. In an example, a location that is closer to a tip of the plate produces a decreased amount of mismatch, as tying the plates together closer to the tips results in less mismatch. Further, if the spring is too close to the base of the plates, there can be a resultant increase in mismatch.

Referring to FIG. 7C, a variation of FIG. 7A is shown in which an example of the boundary of each of spring arms 703A, 703B is shown.

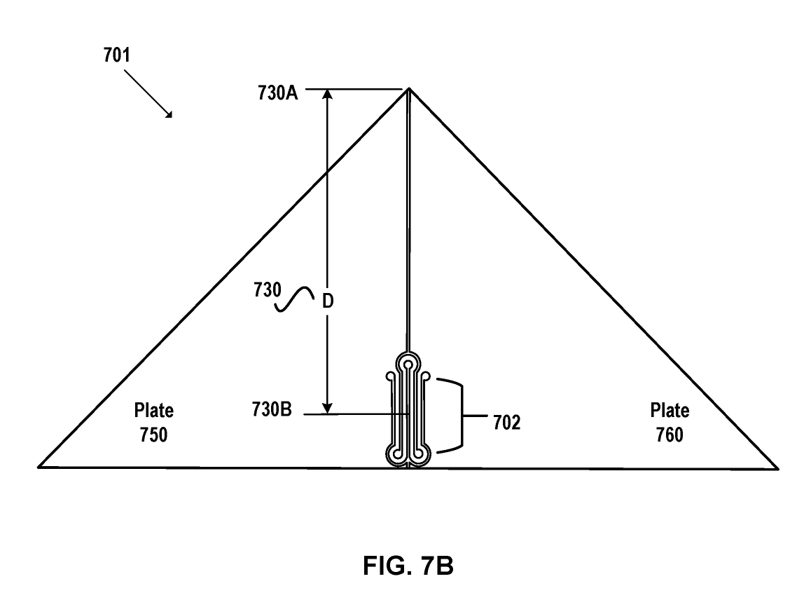

FIG. 8 is an exemplary chart 800 illustrating performance of gap reducing spring designs and geometries, according to certain aspects. In the chart 800, Designs 1.1 and 1.2 are both based on the exemplary gap reducing spring of FIG. 5A. Designs 2.1 and 2.2 are both based on the exemplary gap reducing spring of FIG. 6A. Designs 3.1 and 3.2 are both based on the exemplary gap reducing spring of FIG. 7A.

In certain aspects, increasing the diameter of stress relieving endpoints (C_{dia}) helps to reduce stress at a location where the spring changes direction. Without a stress relieving endpoint, such as a circular stress relief feature, the stress becomes very high at the corner of a turn of a spring. Generally, a turn of a spring includes a portion of the spring in which the spring changes direction. As such, the stress of a spring can become high at the portion of the spring that changes direction. This stress relieving endpoint, however, decreases the acoustic resistance through the diaphragm and so it is important that it is not too large. Thus, the shape of the stress relieving endpoint can be adjusted given the design parameters of each spring. As shown in chart 800 of FIG. 8, the length of a spring can be selected to keep the amount of mismatch low. In some instances, the longer or thinner a plate the more compliant is the plate, which in turn increases mismatch. However, as plates become less compliant (e.g., by being shorter), the in-plane stiffness can also increase.

The gap can be selected to be 1 um. The size of the gap can be selected as such because this size can be built with improved accuracy and precision. The length of the center connecting area (W) for Designs 1.1, 1.2, 2.1, and 2.2 can be selected to be 2 um. If the length of the center connecting area is too short, it could represent a weak point in the design. If the length of the center connecting area is too long, it will extend the length of the gaps unnecessarily.

In certain aspects, the maximum stress due to in-plane residual stress (Max Stress) can be calculated by applying σₓₓ_{_}ᵣₑₛ=400 MPa for the bottom and top layers, σ_{yy}_{_}ᵣₑₛ=435 MPa for the bottom layer and σ_{yy}_{_}ᵣₑₛ=400 MPa for the top layer and then calculating the maximum principal stress in the spring. The sensitivity row (Sensitivity) shows the sensitivity of a microphone with the gap-reducing spring relative to the sensitivity of a microphone without a gap-reducing spring. The mismatch row (Mismatch) shows the mismatch of two adjacent plates connected by the gap-reducing spring with the same residual stresses used for the Max Stress calculation. For reference, the mismatch of two adjacent plates without the spring can be about 15 um.

The chart 800 illustrates three variations of spring design that can be used to achieve similar performance. Nonetheless, one of ordinary skill in the art would appreciate that there are other variations to achieve such performance, and other variations may be used to achieve different performances. As illustrated by chart 800, an increase in the width of spring arms (S_{wid}) from 1 um to 2 um can be undesirable because it can cause an increased reduction in sensitivity and, at the same time, result in more mismatch between adjacent plates. In certain aspects, increased spring arm width can be desirable if it helps to prevent spring breakage.

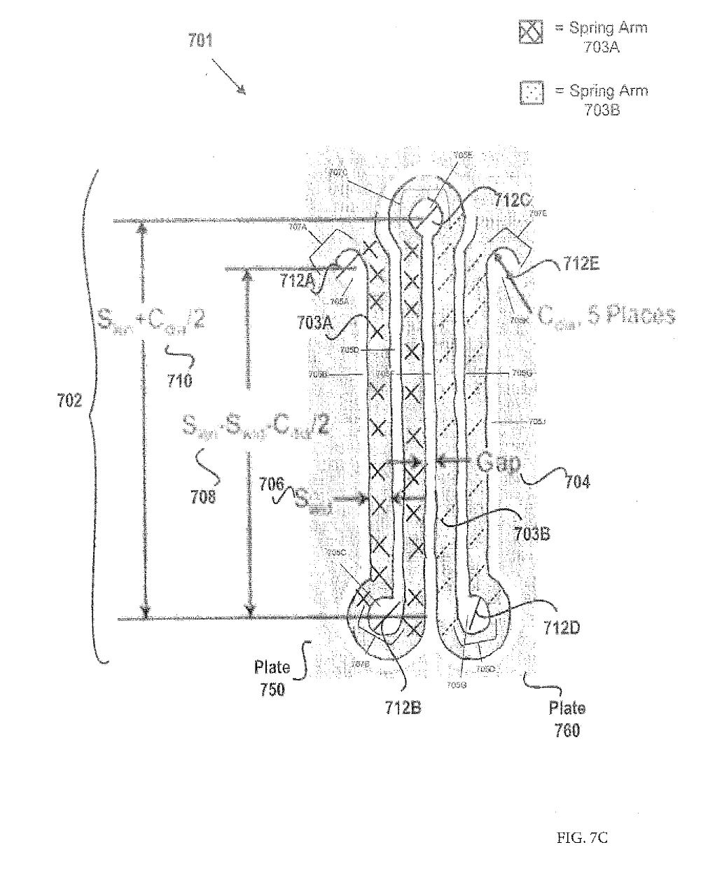

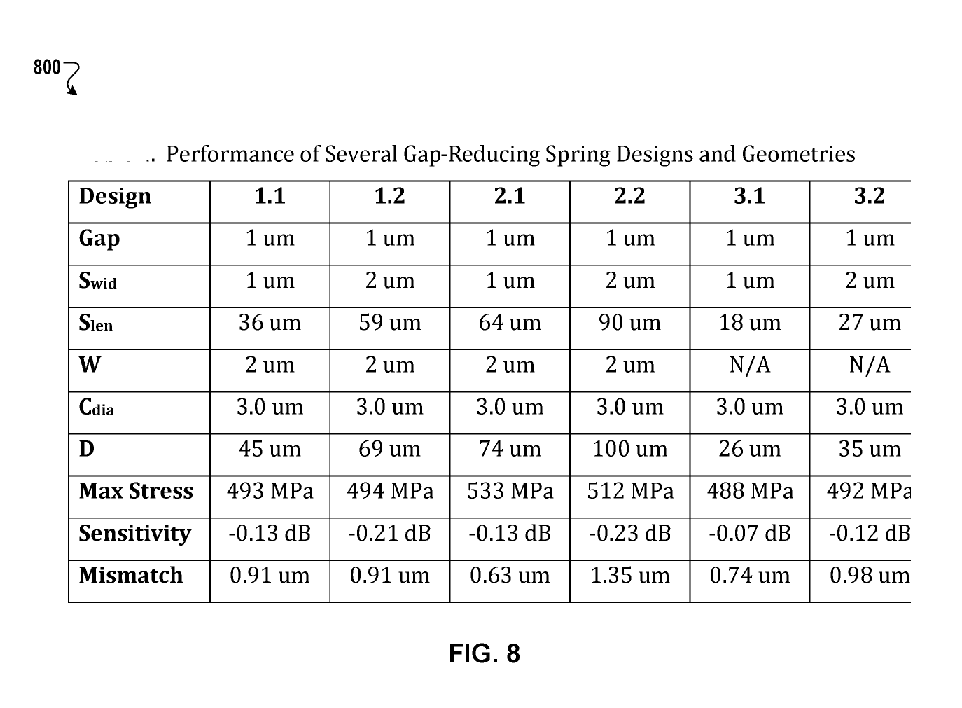

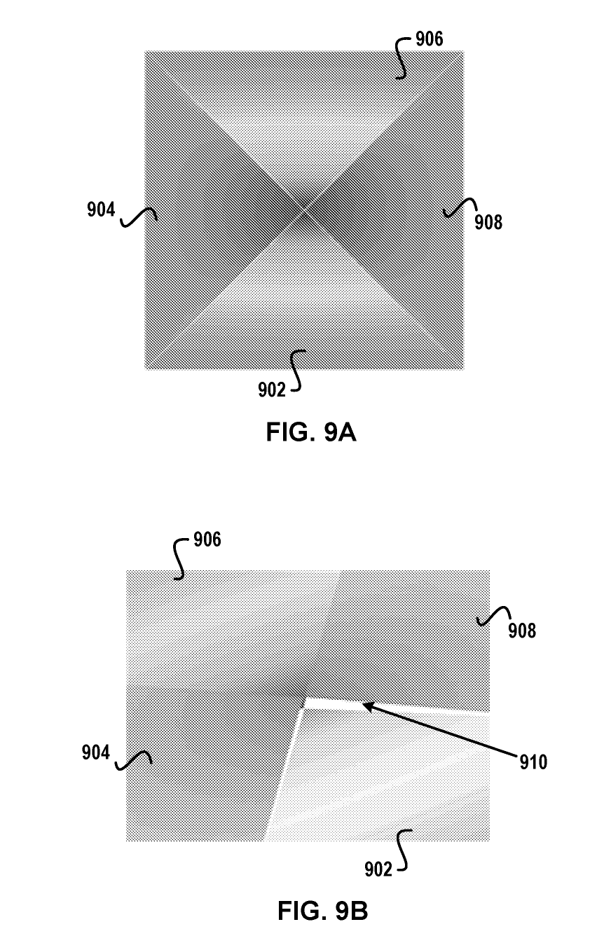

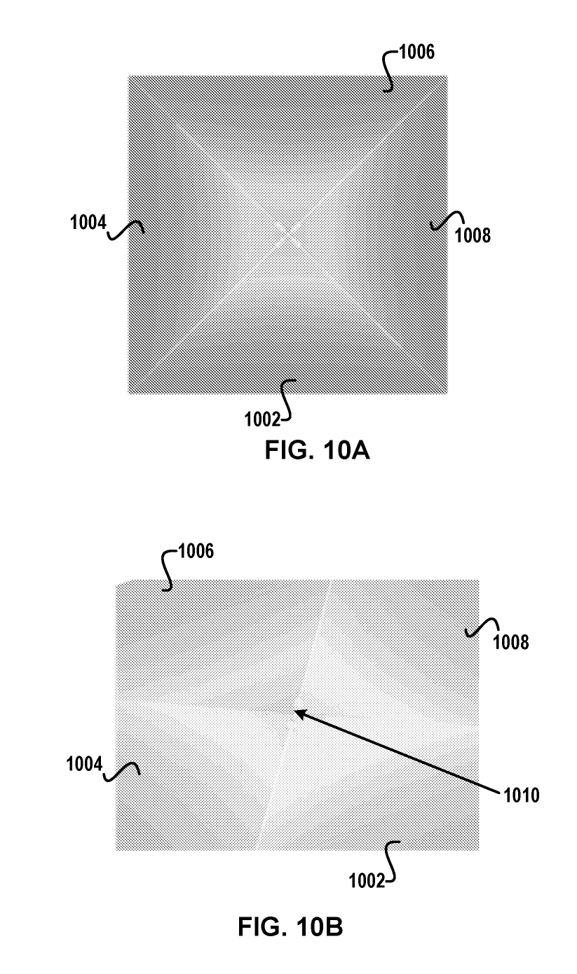

FIGS. 9A, 9B, 10A, and 10B illustrate the improvement provided by a gap reducing spring design. These figures show 2D and 3D images of the improvement in gap size resulting from the gap reducing springs. The applied stress mismatch and scales of FIGS. 9A, 9B, 10A, and 10B are the same.

FIG. 9A illustrates a top view of modeled deflection without gap reducing springs, according to certain exemplary aspects. The top view of modeled deflection without gap reducing springs can include a first triangular plate 902, a second triangular plate 904, a third triangular plate 906, and a fourth triangular plate 908. The difference in X and Y stress can cause adjacent plates to have different vertical deflections, which can ultimately enlarge the gap between plates. For example, the difference in X and Y stress among the modeled deflection of plates can cause the gap 910 between the first modeled plate 902, the second modeled plate 904, and the fourth modeled plate 908 to become larger. Referring to FIG. 9A, the mismatch between adjacent plates can be 15 um. As such, the mismatch between the first triangular plate 902 and the second triangular plate 904 can be 15 um. Additionally, the mismatch between the first triangular plate 902 and the fourth triangular plate 908 can be 15 um.

FIG. 9B illustrates an angled view of modeled deflection without gap reducing springs, according to certain exemplary aspects. The angled view of modeled deflection without gap reducing springs can include a first triangular plate 902, a second triangular plate 904, a third triangular plate 906, and a fourth triangular plate 908. The angled view of modeled deflection without gap reducing springs illustrates an enlarged gap 910 due to the difference in X and Y stress among the modeled deflection of plates. In other words, the difference in X and Y stress between the first triangular plate 902 and the fourth triangular plate 908 can cause the gap 910 between the plates 902 and 908 to increase in size.

FIG. 10A illustrates a top view of modeled deflection with gap reducing springs, according to certain exemplary aspects. The top view of modeled deflection with gap reducing springs can include a first triangular plate 1002, a second triangular plate 1004, a third triangular plate 1006, and a fourth triangular plate 1008. In some aspects, the modeled deflection with gap reducing springs can be a modeled deflection of a microphone with gap reducing springs. By adding gap-reducing springs between each of the adjacent plates 1002, 1004, 1006 and 1008 in the gap controlling geometry, the vertical deflection of adjacent plates can be made more similar, reducing the gap size between plates. For example, in FIG. 10B the mismatch between adjacent plates can be 0.74 um. In certain aspects, the spring design of FIG. 7A can be used to connect each of the four plates 1002, 1004, 1006, and 1008 illustrated in FIGS. 10A and 10B near the tip of each plate.

FIG. 10B illustrates an angled view of modeled deflection with gap reducing springs, according to certain exemplary aspects. The angled view of modeled deflection without gap reducing springs can include a first triangular plate 1002, a second triangular plate 1004, a third triangular plate 1006, and a fourth triangular plate 1008. The angled view of modeled deflection with gap reducing springs illustrates a reduced gap 1010 due to the spring force pulling the plates toward each other. In other words, the X and Y stress between the first triangular plate 902 and the fourth triangular plate 908 remains the same as when a gap reducing spring is not present, however, the spring force can cause the gap 910 between the plates 902 and 908 to decrease in size.

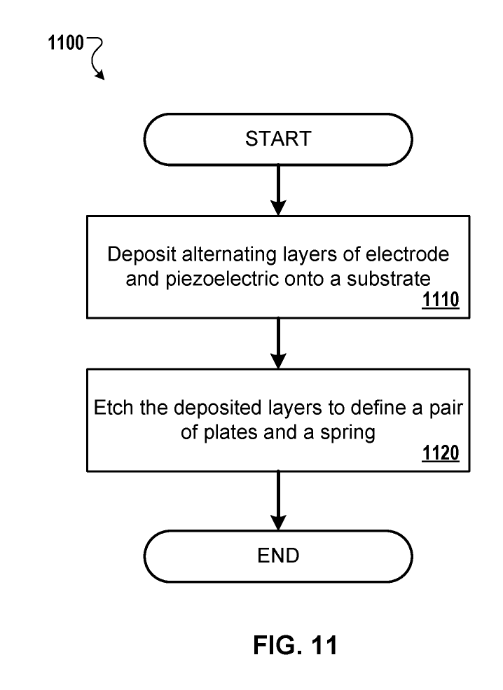

FIG. 11 is a flow chart illustrating an exemplary process 1100 for manufacturing a transducer, according to certain aspects. The process 1100 for manufacturing a transducer describes a method of defining plates and springs of a MEMS transducer. In certain aspects, the process 110 for manufacturing a transducer can describe a method of defining plates and springs of a MEMS transducer that is an acoustic transducer. The acoustic transducer can be a microphone in certain aspects.

At step 1102, alternating layers of electrode and piezoelectric are deposited onto a substrate. In certain aspects, a first electrode layer is deposited on a substrate. A first piezoelectric layer can be deposited on the first electrode layer. A second electrode layer can be deposited on the first piezoelectric layer. As such, alternating layers of electrode and piezoelectric are deposited onto a substrate. In some aspects, alternating layers of electrode and piezoelectric are deposited onto a substrate multiple times. For example, a third electrode layer can be deposited on the substrate. A second piezoelectric layer can be deposited on the third electrode layer. Further, a fourth electrode layer can be deposited on the second piezoelectric layer. Thus, there may be one or more electrode-piezoelectric-electrode compositions.

At step 1104, the deposited layers are etched to define one or more plates and a spring adjacent to the plates. In certain aspects, the deposited layers are etched to define a first plate and a second plate. For example, each plate can include a piezoelectric layer and a pair of electrode layers sandwiching the piezoelectric layer. Each of the plates can include a tapered transducer beam. The first plate and the second plate can be connected in a cantilevered arrangement. Further, each of the first and second plates can include a plate base attached to the substrate, a plate body free from the substrate, and a plate end free from the substrate. As such, if there are a total of two defined plates, there can be two respective plate bases attached to a single substrate, two respective plate bodies free from the substrate, and two plate ends free from the substrate. In some aspects, the plate ends can converge towards a common point. For example, if there are two plates that are each triangular in shape, the tip of the plate end of the first plate and the tip of the plate end of the second plate can both converge towards a common point.

The spring can include a one or more spring arms that are used to decrease vertical deflection mismatch between the first and second plates. As such, the spring arms of the spring can be dimensioned based on the design parameters of the plates, so that the vertical deflection mismatch between the first and second plates is decreased relative to the vertical deflection mismatch of the first and second plates independent of the spring. In certain aspects, the spring is located along a gap between the first plate and the second plate. The spring can be located at a position that decreases the vertical deflection mismatch between the first and second plates. In some aspects, the gap between the first and second plates is reduced as a result of the defined spring. As such, the gap between the first and second plates can decrease in size relative to a size of the gap between the first and second plates independent of the spring.

In certain aspects, a first etching can be performed on the deposited layers to define the first and second plates. A second etching can be performed on the first and second plates to define a spring that is adjacent to the pair of plates. In some aspects, the spring can be built out of material above the first and second plates. In other aspects, the spring can be built out of material below the first and second plates.

A number of implementations have been described. Nevertheless, it will be understood that various modifications may be made without departing from the spirit and scope of the disclosure. For example, various forms of the flows shown above may be used, with steps re-ordered, added, or removed. Additionally, the springs described herein may be included in various types of fabricated devices, including, without limitation, transducers, MEMS transducers, acoustic transducers, MEMS acoustic transducers, microphones and others.

Particular embodiments of the techniques and devices described herein have been described. Other embodiments are within the scope of the following claims. For example, the steps recited in the claims can be performed in a different order and still achieve desirable results.

What is claimed is:

1. A MEMS transducer comprising:
a first plate and a second plate; and
a spring substantially between the first plate and the second plate, the spring comprising first and second spring arms dimensioned to decrease vertical deflection mismatch between the first and second plates, relative to vertical deflection mismatch of the first and second plates independent of the spring.

2. The MEMS transducer of claim 1, wherein a plate comprises a piezoelectric layer and a pair of electrode layers sandwiching the piezoelectric layer.

3. The MEMS transducer of claim 1, further comprising:
a substrate;
wherein the first plate comprises a first plate base, a first plate body and a first plate end;
wherein the second plate comprises a second plate base, a second plate body and a second plate end; and
wherein the first and second plates are connected in a cantilevered arrangement over the substrate by having the first and second plate bases attached to the substrate, the first and second plate ends substantially converging towards a common point, and with each plate body free from the substrate and with each plate end free and unattached.

4. The MEMS transducer of claim 1, wherein a size of a gap between the first and second plates is reduced, relative to a size of a gap between the first and second plates independent of the spring.

5. The MEMS transducer of claim 1, wherein the spring is dimensioned such that a length and a width of the spring provide an acceptable amount of in-plane stiffness of a plate.

6. The MEMS transducer of claim 1, further comprising:
a gap between the first plate and the second plate;
wherein the spring is located along the gap at a position that decreases the vertical deflection mismatch between the first and second plates.

7. The MEMS transducer of claim 6, wherein the gap between the first plate and the second plate is proportional to gaps between the first and second spring arms and the first and second plates.

8. The MEMS transducer of claim 1, wherein the MEMS transducer comprises an acoustic transducer.

9. The MEMS transducer of claim 8, wherein the acoustic transducer is a microphone.

10. The MEMS transducer of claim 1, wherein a plate comprises a tapered transducer beam.

11. The MEMS transducer of claim 1, wherein the spring comprises a plurality of stress relieving endpoints.

12. The MEMS transducer of claim 11, wherein the plurality of stress relieving endpoints prevents the spring from breaking.

13. The MEMS transducer of claim 11, wherein dimensions of the plurality of stress relieving endpoints is based on a calculated stress value at a turn of the spring.

14. The MEMS transducer of claim 1, wherein the spring is dimensioned such that a length and a width of the spring provide an acceptable amount of out-of-plane stiffness of a plate.

15. The MEMS transducer of claim 1, wherein the spring is dimensioned such that a length and a width of the spring is based on a maximum principal stress of the spring.

16. A method comprising:
depositing a first electrode layer on a substrate;
depositing a first piezoelectric layer on the first electrode layer;
depositing a second electrode layer on the first piezoelectric layer;
etching the deposited layers to define a first plate and a second plate that are connected in a cantilevered arrangement over the substrate, each of the plates including a plate base attached to the substrate, a plate body free from the substrate, and a plate end free from the substrate, the first and second plate ends substantially converging towards a common point; and
etching the deposited layers to define a spring that is adjacent to the first and second plates, the spring including a first spring arm and a second spring arm that are each dimensioned to decrease vertical deflection mismatch between the first and second plates, relative to vertical deflection mismatch of the first and second plates independent of the spring.

17. The method of claim 16, wherein a size of a gap between the first and second plates is reduced, relative to a size of a gap between the first and second plates independent of the spring.

18. The method of claim 16, wherein the spring is dimensioned such that a length and a width of the spring provide an acceptable amount of in-plane stiffness of a plate.

19. The method of claim 16, wherein the spring comprises a plurality of stress relieving endpoints.

20. The method of claim 16, wherein the spring is located along a gap between the first plate and the second plate, the spring being located at a position that decreases the vertical deflection mismatch between the first and second plates.
